(19) United States
(12) Patent Application Publication
(10) Pub. No.: US 2025/0208497 A1
(43) Pub. Date: Jun. 26, 2025

(54) EUV MASK BLANK CONNECTIVITY-BASED DEFECT MITIGATION

(71) Applicant: Intel Corporation, Santa Clara, CA (US)

(72) Inventors: Hale Erten, Portland, OR (US); Rafatul Faria, Portland, OR (US); Bikram Baidya, Portland, OR (US)

(73) Assignee: Intel Corporation, Santa Clara, CA (US)

(21) Appl. No.: 18/395,361

(22) Filed: Dec. 22, 2023

(51) Int. Cl. G03F 1/22

(52) U.S. Cl. CPC G03F 1/22

(57) ABSTRACT

Possible positions for forming an absorber pattern on an extreme ultraviolet (EUV) mask blank are determined. The absorber pattern corresponds to a mask layer that in turn corresponds to integrated circuit design. The position of the buried defects identified in the EUV mask blank are analyzed with respect to the absorber pattern placed in the possible positions. If, based in part on connectivity information for the mask layer, all of the buried defects are located within empty regions of the mask layer or coincide with dummy polygons of the mask layer, the possible position is identified as a candidate position. One of the candidate positions is selected as the selected position at which the absorber pattern will be formed on the EUV mask. The selected position can be, for example, the candidate position having the fewest number of buried defects that coincide with dummy regions.

### BACKGROUND

Extreme ultraviolet mask (EUV) photolithography, which uses EUV wavelengths near 13.5 nanometers, enables the fabrication of the smallest critical dimensions in advanced semiconductor manufacturing technology nodes.

### BRIEF DESCRIPTION OF THE DRAWINGS

FIG. 1 is a cross-section of an example EUV mask.

FIG. 2 is a cross-sectional view of an example EUV mask blank comprising buried defects.

FIG. 3 is a first example EUV mask blank connectivity-based defect mitigation method.

FIGS. 4A-4C illustrates example possible positions for forming an absorber pattern on an EUV mask blank surface.

FIG. 5 illustrates four portions of an example mask layer at a possible position for forming an absorber pattern on a surface of an EUV mask blank.

FIG. 6 is an alternative view of the four mask layer portions illustrated in FIG. 5 in which the dummy polygons are removed and various smaller active polygons are replaced with larger active polygons.

FIG. 7 is a block diagram of a first example computing system within which the technologies described herein can be utilized.

FIG. 8 is a second example EUV mask blank connectivity-based defect mitigation method.

FIG. 9 is a block diagram of a second example computing system within which the technologies described herein can be utilized.

FIG. 10 is a block diagram of an example processor unit to execute computer-executable instructions as part of implementing technologies described herein.

### DETAILED DESCRIPTION

Semiconductor manufacturing has become increasingly complex over the years. Since the turn of the century, minimum feature sizes have shrunk by over an order of magnitude as the industry has progressed from the 130 nm to 3 nm technology nodes. Essential to semiconductor manufacturing is the process of photolithography, by which patterns are transferred from a mask (or photomask) onto a wafer. A mask defines the shapes and locations of features to be patterned in a layer of an integrated circuit structure being fabricated on a wafer. For example, one mask can define where oxide regions are located, another mask defines where high-k dielectrics will be located, another mask defines the location of transistor source and drain regions, and yet another mask defines where contacts will be placed. Additional masks are used to define metal layers and intervening via layers. The manufacture of an advanced integrated circuit can require dozens of masks, and in some cases, up to 100 masks.

As masks are how features in integrated circuit structures are realized, any integrated circuit design must ultimately be reduced to a physical design, the level of design abstraction from which masks are generated. The physical design of a transistor, circuit, processor, etc. to be manufactured is often referred to as a “layout” or “mask layout”. As will be discussed in more detail below, a mask layout comprises multiple layers and a single layer can be referred to as a “layer of a mask layout” or a “mask layer”. Electronic design automation (EDA) tools allow processor architects and circuit designers to develop integrated circuit designs at levels of abstraction above the physical design level and are thus spared from having to spend their days drawing polygons in layout tools to realize their designs. Architects typically define their designs using a hardware design language (HDL), such as VHDL or Verilog. Once they have verified that their designs perform as desired, a physical design can be generated automatically, typically by using a library of standard cell layouts. Circuit designers often seek performance or functionality not available using standard cells and often enter their designs into a schematic capture tool. Once their custom designs are finalized, the circuit schematics are handed off to layout designers who manually craft custom physical designs.

Regardless of whether a physical design is generated automatically or manually, it must conform to a set of mask layout design rules established for a manufacturing process. Design rules represent a trade-off between feature density and manufacturability. Being able to print smaller feature sizes can mean more dies can be packed onto a wafer but if the process cannot reliably print the smaller features, the resulting reduction in wafer yield can more than offset the cost reductions gained by being able to print more dies on a wafer.

Once a physical design is cleared of design rule violations and has passed other design validation checks, it is passed to the mask generation phase of an EDA flow. For the layers in an integrated circuit structures that have the smallest geometries in modern semiconductor manufacturing technologies (such as transistor gate width and space, metal width and space for the metal layers having the tightest pitch), extreme ultraviolet (EUV) photolithography can be used, which uses EUV wavelengths near 13.5 nanometers. EUV photolithography involves transferring, using EUV light, a pattern on an EUV mask to an integrated circuit structure under fabrication.

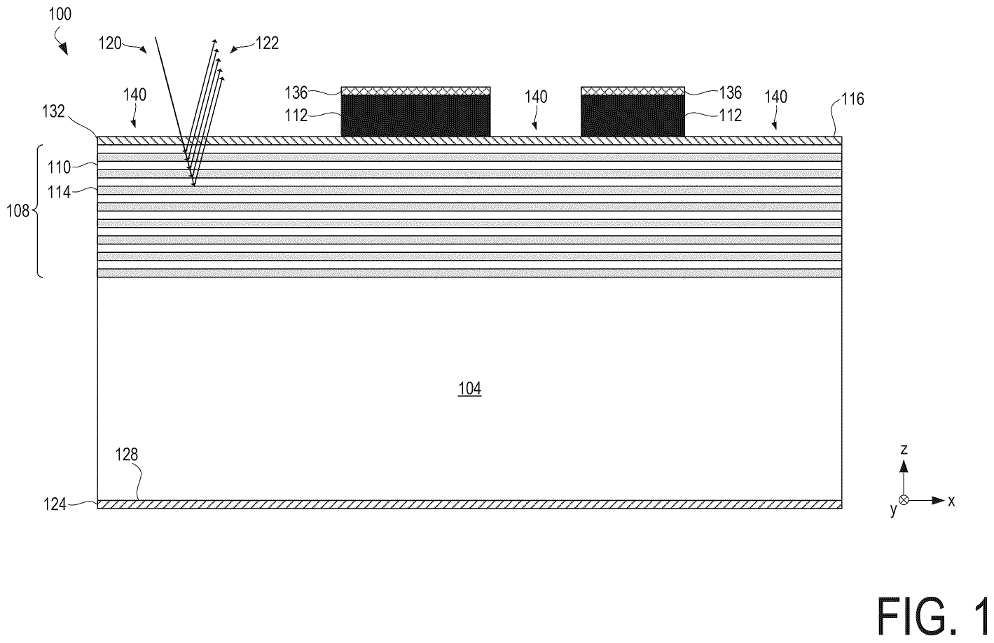

FIG. 1 is a cross-section of an example EUV mask. The EUV mask 100 comprises a substrate 104, a reflector 108, and absorber portions 112. The reflector 108 is located on the substrate 104 and absorber portions 112 are located on a top surface 116 of the EUV mask 100. The reflector 108 comprises multiple alternating layers of a material with a lower index of refraction 110 with a material with a higher index of refraction 114 to form a Bragg reflector that reflects incident EUV light 120 to form reflected EUV light 122. The interfaces between layers in the reflector 108 reflect a portion of the incident EUV light 120 (reflection of the incident EUV light 120 at only the top several interfaces in the reflector 108 are shown in FIG. 1) and the EUV light reflected by the individual interfaces constructively interfere to form reflected EUV light 122. The absorber portions 112 comprise a material that absorbs EUV light and the reflected EUV light 122 thus carries a pattern formed by the absorber portions 112. Focusing optics downstream from the EUV mask 100 can direct the reflected EUV light 122 to an integrated circuit structure, where a layer of photosensitive material on an integrated circuit structure is exposed to the reflected EUV light 122. The photosensitive material can then act as a template for subsequent processing of the integrated circuit structure, resulting in the transfer of the absorber pattern on the EUV mask to the integrated circuit structure.

In some embodiments, the reflector 108 comprises 40-50 alternating layers of molybdenum and silicon. The substrate 104 provides structural support to the reflector 108 and can comprise silicon, quartz, or another suitable material having a low coefficient of thermal expansion. The EUV mask 100 further comprises a conductive coating 124 on a backside 128 of the substrate 104 and an anti-oxidation layer 132 on a top layer of the reflector 108. The conductive coating 124 can enable electrostatic chucking and can comprise chrome nitride or another suitable material. The anti-oxidation layer 132 can comprise ruthenium or another suitable material. The absorber portions 112 are located on the anti-oxidation layer 132 and can comprise tantalum boride nitride or another suitable material. Anti-reflective coating layers 136 are located on top surfaces of the absorber portions 112. The anti-reflective coating layers 136 can comprise tantalum boron oxide or another suitable material.

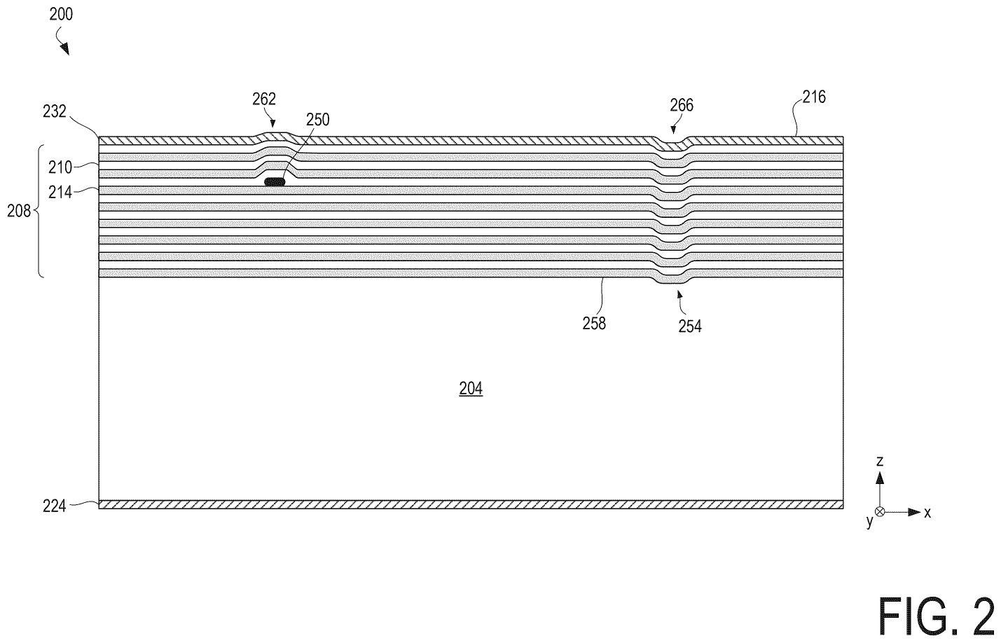

FIG. 2 is a cross-sectional view of an example EUV mask blank comprising buried defects. An EUV mask blank is an EUV mask on which absorber regions have yet to be formed. EUV mask blank 200 is similar in structure to EUV mask 100 and components of the mask blank 200 can perform the same and have the same composition as similarly numbered components described above in regard to EUV mask 100. Mask blank 200 comprises a substrate 204, a reflector 208 comprising multiple alternating layers 210 and 214, and a surface 216 upon which absorber portions are to be formed. The reflector 208 is located on the substrate 204. The mask blank 200 further comprises a conductive coating 224 on a backside of the substrate 204 and an anti-oxidation layer 232 on a top layer of the reflector 208.

EUV mask blanks can comprise buried defects that are introduced during the EUV mask blank manufacturing process. EUV mask blank 200 illustrates two types of buried defects, a particle (or impurity) 250 positioned between layers of the reflector 208 and a pit 254 on a top surface 258 of the substrate 204. It is desirable that the surface of an EUV mask blank (e.g., 116, 216) be sufficiently smooth to enable the transfer of an absorber pattern on the EUV mask to an integrated circuit structure without loss of fidelity of the absorber pattern. Imperfections in the surface of an EUV mask can impact the manufacturability of critical dimension features in a semiconductor manufacturing technology and thus impact yield. As can be seen, the presence of the buried defects 250 and 254 create undulations in the surface 216. The particle 250 causes a bump 262 to be created on the surface 216 and the pit 254 causes a depression 266 to be created on the surface 216.

EUV mask blanks are costly and discarding blanks based on the presence of buried defects can result in a significant cost for mask making operations. The deleterious effects of the presence of buried defects in EUV masks can increase in successive technology generations as the size of a buried defect at which a buried defects begin to impact the photolithography process decreases as critical dimensions continue to shrink.

Disclosed herein are technologies for mitigating the effects of buried defects in EUV mask blanks based on mask connectivity information. In general, an absorber pattern to be formed on an EUV mask blank is shifted over a range of possible positions where the absorber pattern can be formed on a surface of the EUV mask blank and the position of buried defects in the EUV mask blank is analyzed relative to absorber portions in the absorber pattern, which respond to polygons in a mask layer. Possible absorber pattern placement positions for which all of the buried defects are located in empty regions of the mask layer or coincide with dummy polygons of the mask layer, which are determined based on connectivity information for polygons in the mask layer, are identified as candidate positions. The connectivity information for the mask layer indicates polygons that are physically connected to a polygon on another mask layer or that are conductively coupled to a device, such as active device (e.g., transistor) or passive device (e.g., resistor, capacitor) device. A polygon can be conductively coupled to a device via structures located on one or more mask layers (e.g., by one or more metal, via, and/or contact layers). Once all of the possible positions in a possible position space have been analyzed and a set of candidate positions have been identified, one of the candidate positions is selected for positioning the absorber pattern on the EUV mask blank. The selected candidate position can be, for example, the candidate position for which all of the buried defects are located within empty regions or the candidate position that has the fewest number of buried defects coinciding with dummy polygons. EUV mask blanks can comprise additional types of defects in addition to buried defects, such as surface defects, and the connectivity-based defect mitigation technologies described herein can be used for those types of defects as well.

The EUV mask blank defect mitigation technologies described herein have at least the advantage of providing cost savings to mask production operations through the use of EUV mask blanks comprising buried defects that may otherwise be discarded.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. As used herein, the phrase “conductively coupled” refers to layers or components that are coupled to facilitate the flow of current between them. For example, a polygon on one metal mask layer can be conductively coupled to a polygon on another metal mask layer if there is a via between them, and a polygon on a metal mask layer can be conductively coupled to a terminal (gate, source, drain, body) of a transistor by polygons on interval metal and via layers. Furthermore, the terms “comprising,” “including,” “having,” and the like, as used with respect to embodiments of the present disclosure, are synonymous.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

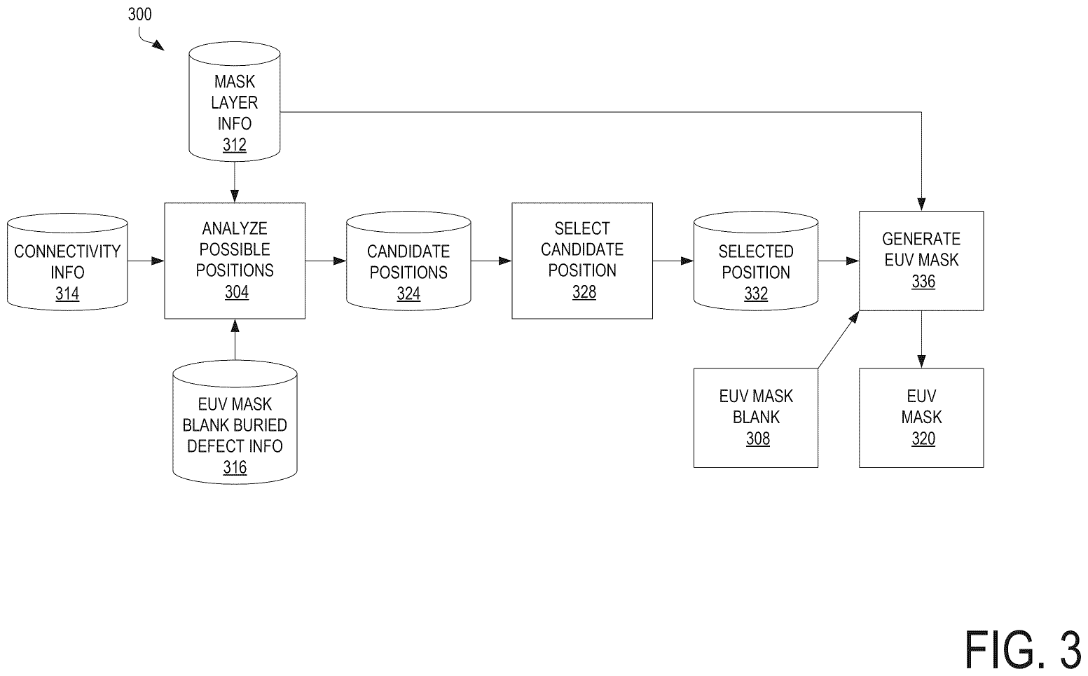

FIG. 3 is a first example EUV mask blank connectivity-based defect mitigation method. At 304 in the method 300, possible positions for forming an absorber pattern on a surface of an EUV mask blank 308 are analyzed to determine which of the possible positions result in a set of identified buried defects in the EUV mask blank 308 being located within empty regions or coinciding with one or more dummy polygons in the mask layer that the absorber pattern corresponds to.

A possible position of the absorber pattern on the EUV mask blank surface is analyzed using mask layer information 312 and EUV mask blank buried defect information 316. The mask layer information 312 comprises information indicating the location and shape of polygons that define a mask layer design, information that will be used by an EUV mask-making tool to form an absorber pattern on the EUV mask blank 308 to produce an EUV mask 320. In some embodiments, the mask layer information 312 can comprise information indicating polygons that have been subjected to resolution enhancement techniques, such as optical proximity correction (OPC) that can compensate for distortion effects due to printing features with a wavelength larger than minimum features as well as those inherent in deposition, etching, and other processing steps. In other embodiments, the polygons represented in the mask layer information 312 can be polygons that have not been subjected to resolution enhancement techniques. That is, the polygons can comprise simple rectangular polygons.

The EUV mask buried defect information 316 comprises information indicating the location, size, and shape of buried defects that have been identified in the EUV mask blank 308. In some embodiments, the buried defect information 316 can be generated by an EUV mask blank defect detection tool. It is possible that the EUV mask blank 308 comprises buried defects in addition to those represented in the buried defect information 316. This can be due to, for example, buried defects having a size below a buried defect threshold size being ignored for the sake of the defect mitigation methods described herein or buried defects being too small to be detected by EUV mask defect detection techniques. Buried defects can be represented by the buried defect information 316 in any suitable manner, such as by shape, location, and size (e.g., shape= “rectangle”; x-position=100, y-position=150; length=5, width=10), or polygons (e.g., a set of vertices with x-y coordinates for each vertex).

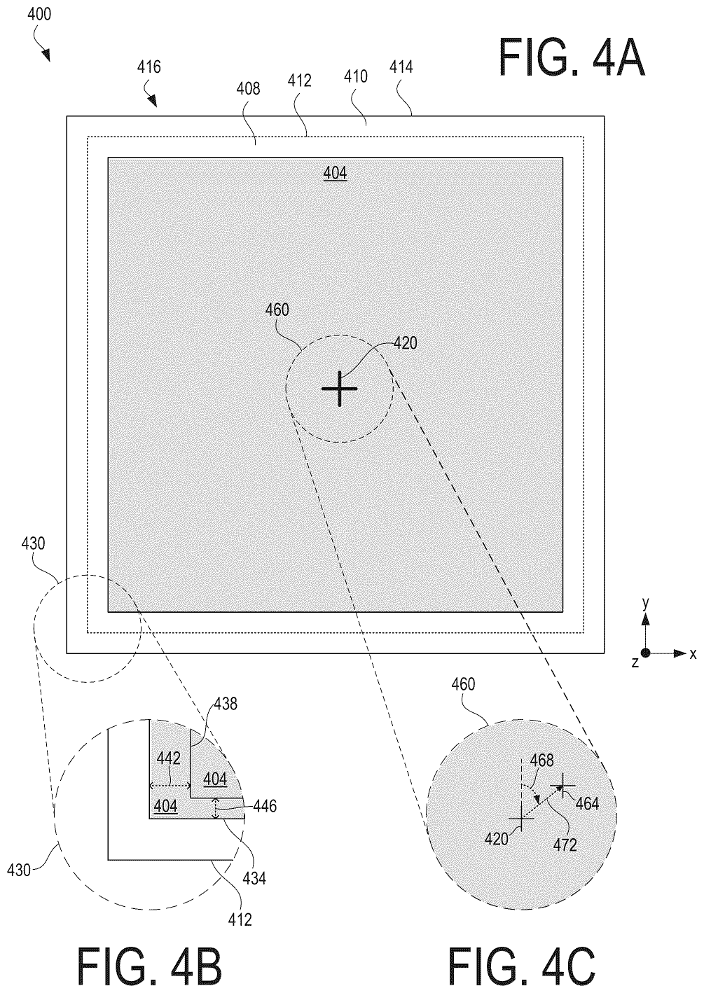

FIGS. 4A-4C illustrate example possible positions for forming an absorber pattern on an EUV mask blank surface. FIG. 4A illustrates a top-down view 400 of an example position of an absorber pattern 404 on a surface 408 of an EUV mask blank 416. The absorber pattern 404 is positioned in the center of an available area 412 on the surface 408 of the EUV mask blank 416 where the absorber pattern 404 can be positioned. As can be seen, as the size of the absorber pattern 404 is smaller than the available area 412, there is room for the absorber pattern 404 to be moved around within the available area 412.

The possible positions where the absorber pattern 404 can be located within the available area 412 that are analyzed as possible candidate positions are positions where the absorber pattern 404 can be positioned within the available area 412. The number of possible positions that could be analyzed is thus based in part on the size of the absorber pattern 404 relative to the size of the available area 412. The smaller the size of the absorber pattern 404, the more the absorber pattern 404 can be moved within the available area 412, and the greater the number of possible positions that could be analyzed. In some embodiments, the mask layout corresponding to the absorber pattern to be formed on the mask blank surface can comprise multiple instances of an integrated circuit design arranged in an array (e.g., a 3×3, 4×3 array) to maximize the use of the available area 412. Thus, as used herein, the term “mask layout” can refer to a mask layout that incorporates one or more instances of an integrated circuit design. An area 410 between the outer edges (e.g., edge 414) of the EUV mask blank 416 and the available area 412 for the absorber pattern 404 can be reserved for barcodes or other information pertaining to the EUV mask blank, the mask layer, and/or the integrated circuit design corresponding the mask layer, as well as additional structure or features, such as alignment features for aligning the EUV mask with features already formed on an integrated circuit structure.

Another factor that can determine which possible positions for forming the absorber pattern 404 within the available area 412 are analyzed is how much the absorber pattern 404 is moved (or stepped) between physically adjacent possible positions. If the step size between physically adjacent possible positions is kept constant, a larger number of possible positions are available for analysis for smaller absorber patterns than larger ones. In embodiments where available computing resources are limited or computing resources and/or runtime are wished to be capped, the step size can be adjusted based on the absorber pattern size to keep the number of possible positions analyzed below a maximum number. If there are no such (or lesser) computing resourcing constraints, the number of possible positions can increase with decreasing absorber pattern size.

In some embodiments, possible positions are indicated as being physically offset from a base position on an EUV mask surface. In some embodiments, the base position is a position at which an absorber pattern would be formed on an EUV mask blank in an EUV mask making flow if the absorber pattern were not to be formed at an offset position from the base position in according to the technologies disclosed herein. In some embodiments, the center of the area 412 can be used as a base position, as represented by cross 420 illustrated in FIG. 4A. In other embodiments, the base position can be any position located in the area 412 for which the absorber pattern 404 fits within the area 412.

FIG. 4B illustrates an example possible position that is offset from a base position in an orthogonal manner. FIG. 4B is a magnified view of a bottom-left portion 430 of FIG. 4A. FIG. 4B shows the absorber pattern 404 located at a base position, represented by outline 434 and at an offset possible position represented by outline 438. The offset position represented by outline 438 is offset from the base position by an x-offset 442 and an y-offset 446. The x-offset 442 can be a multiple of an x-offset step size and the y-offset can be a multiple of a y-offset step size. The x-offset and y-offset step sizes can be the same or different.

The range of x-offsets and y-offsets that can be covered by a set of possible positions can be determined by the differences between the x- and y-dimensions of the available area 412 and the absorber pattern 404. That is, the range of x-offsets can be determined by the difference between the length of the available area 412 (the distance that the available area 412 extends in the x-dimension) and the length of the absorber pattern 404 (the distance that the absorber pattern 404 extends in the x-dimension), and the range of y-offsets can be determined by the difference between the width of the available area 412 (the distance that the available area 412 extends in the y-dimension) and the width of the absorber pattern 404 (t the distance that the absorber pattern 404 extends in the y-dimension). In some embodiments, the x-offset range and y-offset range can be about 200 microns in mask dimension units. In some embodiments, EUV light reflected from an EUV mask passes through downstream focusing optics before reaching a wafer. In some embodiments, the focusing optics can demagnify the EUV light reflected from an EUV mask, such as by a factor of four in some embodiments. In such embodiments, an x- or y-offset range of 200 microns in mask dimension units translates to a physical dimension of 50 microns. In some embodiments, the number of possible positions analyzed can be in the range of 100 to 200 positions.

FIG. 4C illustrates an example possible position that is offset from a base position in a radial fashion. FIG. 4C is a magnified view of center portion 460 of FIG. 4A. FIG. 4B shows the absorber pattern 404 located at a base position, represented by the cross 420, and at an offset position represented by cross 464. The shifted position is offset from the base position by an angle offset 468 and a radial offset 472. The angle offset 468 can be a multiple of an angle-offset step size and the radial offset 472 can be a multiple of a radial-offset step size.

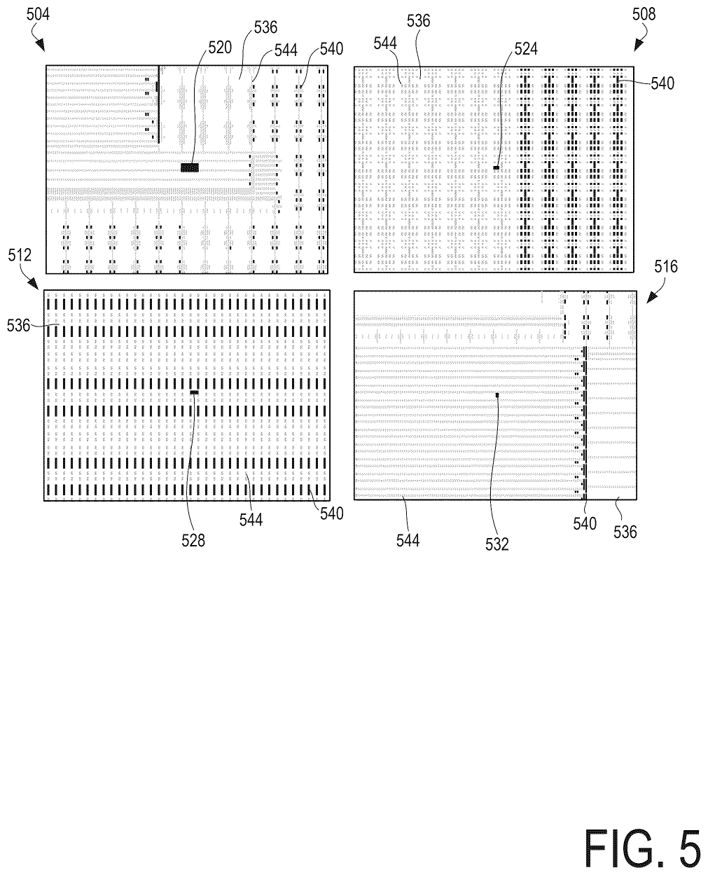

Returning to FIG. 3, as stated above, placement of the absorber pattern at each of a set of possible positions on the EUV mask blank surface is analyzed at 304 to determine whether the plurality of buried defects represented by the buried defect information 316 are located within zero or more empty regions of the mask layer or coincide with zero or more dummy polygons of the mask layer. That is, the absorber pattern is analyzed in each of the possible positions to determine if the individual buried defects are located within an empty region in the mask layer or coincide with one or more dummy polygons of the mask layer. The empty regions of a mask layer are the regions of a mask layer corresponding to portions of the EUV mask surface where absorber portions would not be present, such as regions 140 of the surface 116 of the EUV mask 100 in FIG. 1 and regions 536 in FIG. 5. Buried defects in an EUV mask blank approved for use in manufacturing by an integrated circuit component manufacturer can be up to hundreds of nanometers in size and are thus capable of spanning a large number of polygons in a mask layout. For the purposes of this application, a buried defect that coincides with one or more dummy polygons can refer to a buried defect that is located entirely within a dummy polygon or at least partially overlaps with one or more dummy polygons. A buried defect that encompasses a dummy polygon is considered to at least partially overlap the dummy polygon.

Dummy polygons in a mask layer are polygons that are not connected to a polygon on another mask layer or are not connected to an active or passive device (such as a transistor, resistor, or capacitor). Dummy polygons are typically part of “fill patterns” that can fill portions of what would otherwise be empty region in a mask layer to ensure that the local and/or global polygon density meets a threshold density, which can improve manufacturability by reducing the variation in surface conditions across an integrated circuit structure during processing. Dummy polygons can also be added to ends of a repeating pattern of polygons that correspond to active devices. These dummy polygons can cause the active device polygons located at the ends and the middle of the repeating pattern to have similar sets of neighboring polygons. This can cause integrated circuit structure features associated with active device polygons located at the ends and the middle of the repeating pattern to be fabricated with less variability, which can improve manufacturability. Dummy polygons can also be referred to herein as sacrificial or non-critical polygons.

Connectivity information 314 comprises connectivity information for one or more polygons represented in the mask layer information 312. The connectivity information 314 can be in any type of data format and can comprise any type of data structure. In some embodiments, the connectivity information 314 comprises one or more graph data structures indicating the connectivity of polygons in a mask layout. A connectivity graph can represent polygon connectivity information in various ways. For example, the vertices of a graph can correspond to individual polygons and the edges of the graph can represent conductive couplings between the polygons. In such embodiments, a dummy polygon can be represented by a vertex that has no edges or a vertex to which only vertices associated with polygons that are not part of an active device may be reached through traversal of the graph from the vertex.

In another connectivity graph example, vertices of the graph represent elements in an integrated circuit design and the edges represent conductive couplings between the elements. Thus, determining whether a buried defect coincides with a particular polygon for a possible position can comprise identifying a vertex in a connectivity graph that corresponds to the particular polygon and traversing the graph to see if a vertex corresponding to an active device can be reached. If so, the particular polygon is identified as not being a dummy polygon. Polygons in a mask layout that are not dummy polygons can be referred to herein as active polygons. In such embodiments, the vertices and edges can be associated with polygons in the mask layout that correspond to the elements represented by the vertices. A dummy polygon can be determined by its absence from such a connectivity graph. In some embodiments, connectivity graphs can be created in advance of determining a selected position that an absorber pattern is to be formed on an EUV mask by, for example, an electronic design automatic (EDA) software tool. The connectivity information 314 can comprise connectivity information for fewer than all of the polygons represented in the mask layer information 312.

Connectivity information for polygons in a mask layer can be represented in the connectivity information 314 in other ways. In some embodiments, the connectivity information 314 can represent a dummy polygon via information indicating that the polygon is not conductively coupled to another polygon or an active polygon via information indicating that the polygon is conductively coupled to a device. In other embodiments, inclusion of information indicating a polygon in the connectivity information 314 can indicate that the polygon is a dummy polygon (or, in still other embodiments, that the polygon is an active polygon). In other embodiments, the connectivity information 314 can comprise information indicating an element in an integrated circuit design that the polygon is conductively coupled to, such as another polygon (optionally including information indicating what layer the other polygon is located on) or device (optionally including information about the device, such as device type (e.g., active, passive, transistor, resistor, capacitor), and information on how the polygon is conductively coupled to the device (such as which terminal of a device (e.g., gate, source, drain, or body of transistor) the polygon is conductively coupled to).

In some embodiments, in analyzing a possible position, only polygons within the vicinity of a buried defect are analyzed to determine if they are a dummy polygon or an active polygon. This can reduce the computational load of analyzing a possible position. In some embodiments, polygons within the possible position step size (which, as indicated above, can be 200 microns in both the x- and y-directions in some embodiments) plus the size of the buried defects plus some margin (which, in some embodiments can be about five microns) is analyzed. In other embodiments, polygons within 0.25 microns, 0.5 microns, 1.0 microns, or another distance are analyzed.

Possible positions for forming an absorber pattern on an EUV mask blank for which the plurality of buried defects represented by the buried defect information 316 are located within zero or more empty regions or coincide with zero or more dummy polygons of the mask layer represented by the mask layer information 312 are identified as candidate positions 324.

FIG. 5 illustrates four portions of an example mask layer represented by the mask layer information 312 and corresponding to a possible position for forming an absorber pattern on a surface of the EUV mask blank 308. Portions 504, 508, 512, and 516 comprise empty region 536 (white spaces) and mask layer polygons represented by the mask layer information 312 that correspond to absorber regions that will be formed on the EUV mask blank 308. The mask layer polygons comprise active polygons 540 (dark polygons) and dummy polygons 544 (light grey polygons). Buried defects 520, 524, 528, and 532 are located in portions 504, 508, 512, and 516, respectively, and all four buried defects coincide with at least one of the dummy polygons 544.

Thus, if candidate positions were determined based on whether the buried defects 520, 524, 528, and 532 were located only in empty regions 536, the possible position illustrated in FIG. 5 would not qualify as a candidate position. However, as the connectivity-based defect mitigation technologies disclosed herein consider a candidate position to be a possible position where the buried defects can coincide with dummy polygons as well as be located in empty regions or the possible position illustrated in FIG. 5 may be a candidate position.

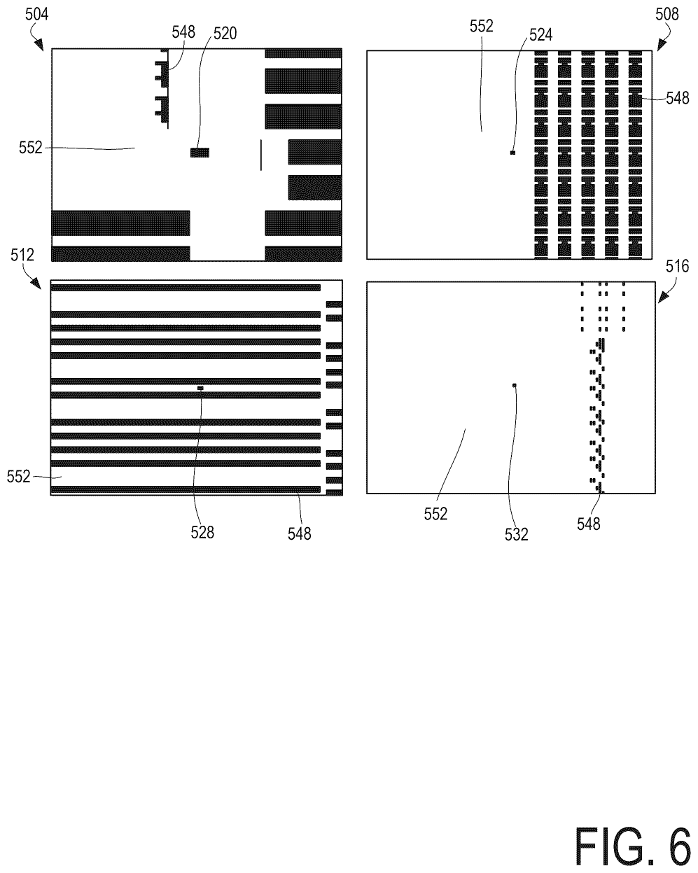

FIG. 6 is an alternative view of the four mask layer portions illustrated in FIG. 5 in which the dummy polygons are removed, and various smaller active polygons are replaced with larger active polygons. The larger active polygons can be the union of multiple smaller active polygons or be a bounding box that bounds multiple smaller active polygons. Removal of the dummy polygons and the replacement of numerous smaller active polygons 540 illustrated in FIG. 5 with fewer larger active polygons 548 illustrated in FIG. 6 can aid in reducing the computational load in determining whether a buried defect is located in an empty region or coincides with one or more dummy polygons. The problem of determining whether all buried defects are located in an empty region or coincide with one or more dummy polygons is reduced to the problem of determining, for each buried defect, whether the buried defect overlaps with a fewer number of larger active polygons (e.g., polygons 548). As can be seen, all four of the buried defects 520, 524, 528, and 532 do not coincide with any of the larger active polygons 548 and are located in regions 552 that are the union between the empty regions 536 and the dummy polygons 544 of a mask layer.

Returning again to FIG. 3, after one or more candidate positions have been determined, one of the candidate positions is selected as the position (the selected position) on the surface of the EUV mask blank 308 at which the absorber pattern is to be formed. In some embodiments, if a candidate position is located at a base position, that candidate is selected as the selected position. In some embodiments, a candidate position in which all of the buried defects are located in empty regions in the mask layer is selected as the selected position. In other embodiments, a candidate position in which all of the buried defects are at least a threshold distance away from a nearest polygon in the mask layer is selected as the selected position. In still other embodiments, the candidate position having the lowest number of buried defects that coincide with one or more dummy polygons in the mask layer is selected as the candidate position. In yet other embodiments, the candidate position having the largest sum of minimum distances from the individual buried defects within an empty region of the zero or more empty regions of the mask layer to a nearest polygon in the mask layer is selected as the selected position. In other embodiments, the selected position is the candidate position for which a minimum distance from any of the buried defects located within an empty region to any of the polygons in the mask layer is the greatest among the candidate positions.

The selected candidate position is represented by selected position information 332. The selected position can be indicated in the selected position information 332 as, for example, an offset from a base position (e.g., an orthogonal or a radial offset) or an absolute position within a coordinate system utilized by an EUV mask-making tool.

At 336, an EUV mask 320 is formed in which an absorber pattern corresponding to the design of the mask layer represented by the mask layer information 312 is formed on a surface of the EUV mask blank 308 at the selected position represented by the selected position information 332. The EUV mask 320 is formed by an EUV mask-making tool. In some embodiments, the EUV mask-making tool generates the EUV mask at 336 in the method 300 and the remainder of the method (e.g., 304, 328) is performed by one or more other computing devices or systems. For example, an EDA software tool operating on a computing system that is not part of an EUV mask-making tool can perform 304 and 328 in method 300 and provide selected position information 332 to an EUV tool. In other embodiments, the method 300 can be performed by an EUV mask-making tool.

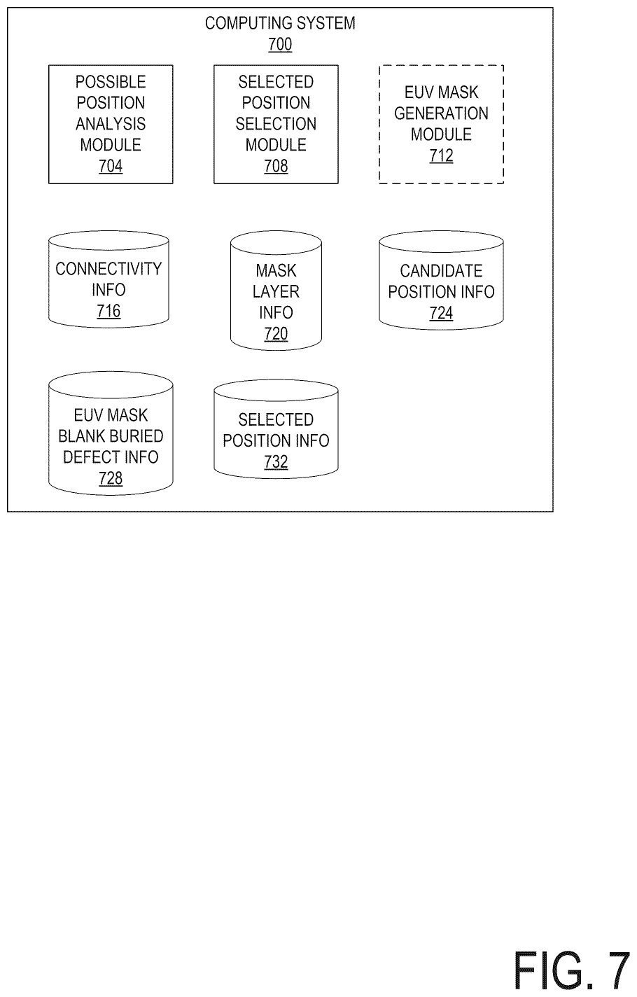

FIG. 7 is a block diagram of a second example computing system in which technologies described herein may be implemented. The computing system 700 comprises a possible position analysis module 704, a selected position selection module 708, and an EUV mask generation module 712. The computing system 700 further comprises a connectivity information store 716, a mask layer information store 720, a candidate positions information store 724, an EUV mask blank buried defect information store 728, and a selected position information store 732. The possible position analysis module 704 analyzes, using connectivity information in the connectivity information store 716, whether an absorber pattern located at a possible position on an EUV mask blank will result in all buried defects identified in the EUV mask blank buried defect information store 728 are located within empty regions or coincide with dummy regions of a mask layer. If so, the analysis module 704 stores the possible position as a candidate position in the candidate position information store 724. The selected position selection module 708 selects a selected position for forming an absorber pattern on an EUV mask blank from a set of candidate positions stored in the candidate position information store 724. The computing system can be any computing system described or referenced herein, or any other computing system. In some embodiments, the modules 704 and 708 can be part of an EDA software tool.

In embodiments where the computing system 700 is an EUV mask-making tool, the computing system can further comprise an EUV mask generation module 712 that causes the EUV mask-making tool to generate an EUV mask based on mask layer information stored in the mask layer information store 720 and selected position information stored in the selected position information store 732. The stores 716, 720, 724, 728, and 732 can be any memory or storage described or referenced herein, or any other memory or storage. In some embodiments, all or a part of any of the stores 716, 720, 724, 728, or 732 can be external or remote to the computing system 700.

It is to be understood that FIG. 7 illustrates one example of a set of modules that can be included in a computing system. In other embodiments, a computing system can have more or fewer modules than those shown in FIG. 7. Further, separate modules can be combined into a single module, and a single module can be split into multiple modules. The modules shown in FIG. 7 can be implemented in software, hardware, firmware, or combinations thereof.

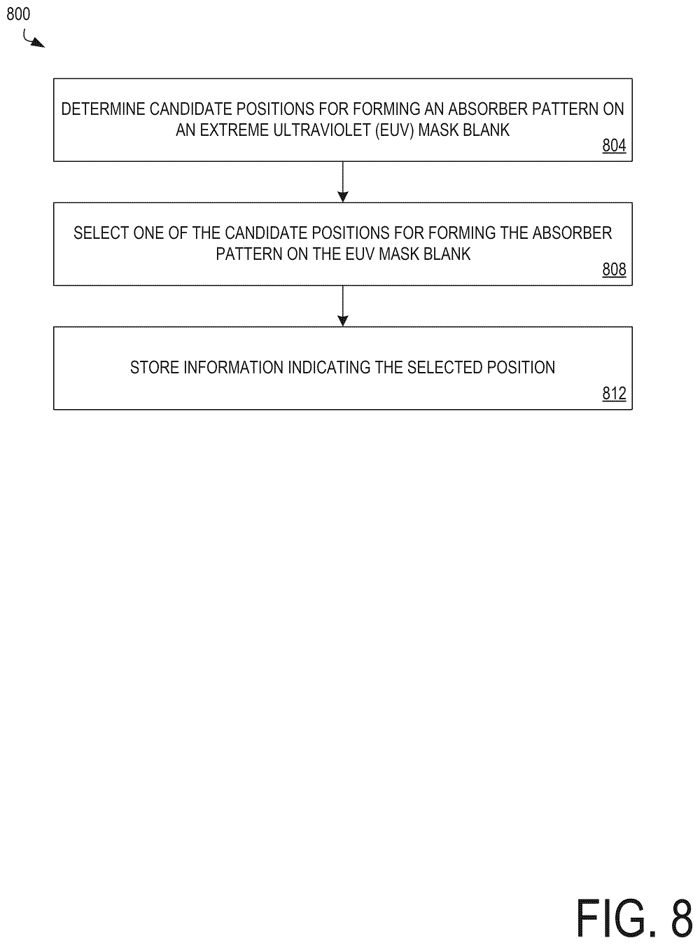

FIG. 8 is a second example EUV mask blank connectivity-based defect mitigation method. The method 800 can be performed by an EDA software tool. At 804, one or more candidate positions for forming an absorber pattern on an extreme ultraviolet (EUV) mask blank are determined, the EUV mask blank comprising a plurality of buried defects, the absorber pattern comprising a plurality of absorber regions, the absorber pattern corresponding to a mask layer, the mask layer corresponding to an integrated circuit design, the mask layer comprises a plurality of polygons, wherein determining the one or more candidate positions is based at least in part on connectivity information for one or more polygons of the plurality of polygons, wherein, for individual of the one or more candidate positions, the plurality of buried defects are located within zero or more empty regions of the mask layer or coincide with zero or more dummy polygons of the mask layer. At 808, one of the one or more candidate positions for forming the absorber pattern on the EUV mask blank is selected as a selected position for forming the absorber pattern on the EUV mask blank. At 812, information indicating the selected position for forming the absorber pattern on the EUV mask blank is stored.

In other embodiments, the method 800 can further comprise one or more additional elements. For example, the method 800 can further comprise sending information indicating the selected position for forming the absorber pattern on the EUV mask blank an EUV mask making tool. In another example, the method 800 can further comprise, using an EUV mask making tool, forming the absorber pattern on a surface of the EUV mask blank, a position of the absorber pattern on the surface of the EUV mask based at least in part on the selected position for forming the absorber pattern on the EUV mask blank.

The technologies described herein can be performed by or implemented in any of a variety of computing systems, including mobile computing systems (e.g., handheld computers, tablet computers, laptop computers, 2-in-1 convertible computers, portable all-in-one computers), non-mobile computing systems (e.g., desktop computers, servers, workstations, rack-level computing solutions (e.g., blade, tray, or sled computing systems)), and embedded computing systems (e.g., computing systems that are part of manufacturing equipment, such as an EUV mask-making tool). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

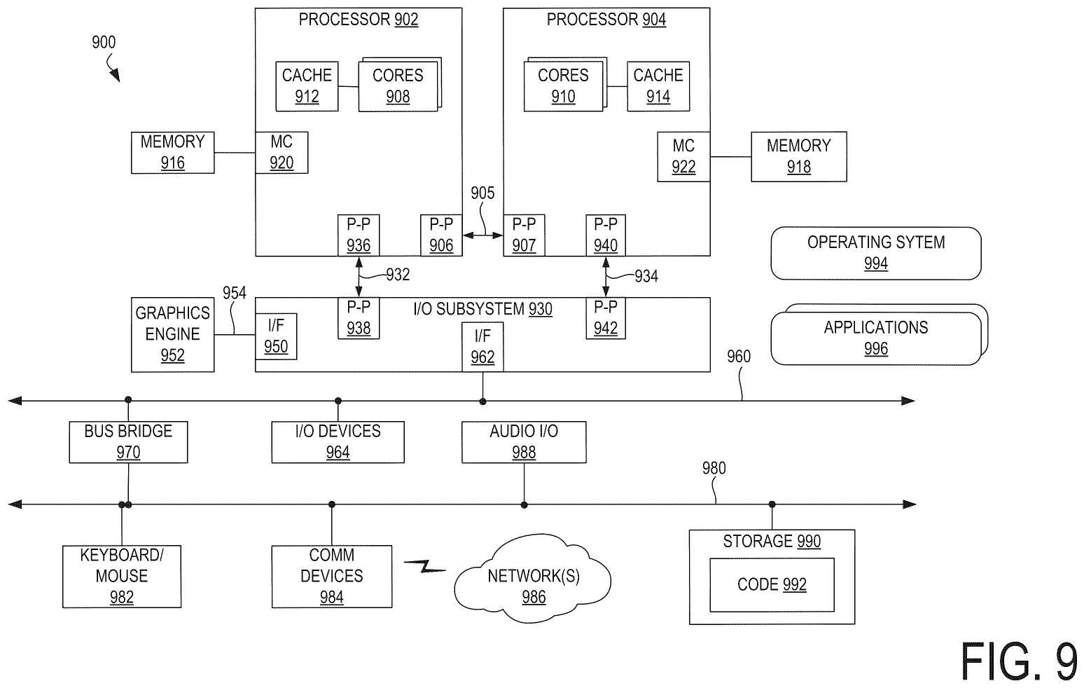

FIG. 9 is a block diagram of a second example computing system in which technologies described herein may be implemented. Generally, components shown in FIG. 9 can communicate with other shown components, although not all connections are shown, for ease of illustration. The computing system 900 is a multiprocessor system comprising a first processor unit 902 and a second processor unit 904 comprising point-to-point (P-P) interconnects. A point-to-point (P-P) interface 906 of the processor unit 902 is coupled to a point-to-point interface 907 of the processor unit 904 via a point-to-point interconnection 905. It is to be understood that any or all of the point-to-point interconnects illustrated in FIG. 9 can be alternatively implemented as a multi-drop bus, and that any or all buses illustrated in FIG. 9 could be replaced by point-to-point interconnects.

The processor units 902 and 904 comprise multiple processor cores. Processor unit 902 comprises processor cores 908 and processor unit 904 comprises processor cores 910. Processor cores 908 and 910 can execute computer-executable instructions in a manner similar to that discussed below in connection with FIG. 9, or other manners.

Processor units 902 and 904 further comprise cache memories 912 and 914, respectively. The cache memories 912 and 914 can store data (e.g., instructions) utilized by one or more components of the processor units 902 and 904, such as the processor cores 908 and 910. The cache memories 912 and 914 can be part of a memory hierarchy for the computing system 900. For example, the cache memories 912 can locally store data that is also stored in a memory 916 to allow for faster access to the data by the processor unit 902. In some embodiments, the cache memories 912 and 914 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 900 is shown with two processor units, the computing system 900 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 900 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 902 and 904 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 902 and 904 further comprise memory controller logic (MC) 920 and 922. As shown in FIG. 9, MCs 920 and 922 control memories 916 and 918 coupled to the processor units 902 and 904, respectively. The memories 916 and 918 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 920 and 922 are illustrated as being integrated into the processor units 902 and 904, in alternative embodiments, the MCs can be external to a processor unit.

Processor units 902 and 904 are coupled to an Input/Output (I/O) subsystem 930 via point-to-point interconnections 932 and 934. The point-to-point interconnection 932 connects a point-to-point interface 936 of the processor unit 902 with a point-to-point interface 938 of the I/O subsystem 930, and the point-to-point interconnection 934 connects a point-to-point interface 940 of the processor unit 904 with a point-to-point interface 942 of the I/O subsystem 930. Input/Output subsystem 930 further includes an interface 950 to couple the I/O subsystem 930 to a graphics engine 952. The I/O subsystem 930 and the graphics engine 952 are coupled via a bus 954.

The Input/Output subsystem 930 is further coupled to a first bus 960 via an interface 962. The first bus 960 can be a Peripheral Component Interconnect Express (PCIe) bus or any other type of bus. Various I/O devices 964 can be coupled to the first bus 960. A bus bridge 970 can couple the first bus 960 to a second bus 980. In some embodiments, the second bus 980 can be a low pin count (LPC) bus. Various devices can be coupled to the second bus 980 including, for example, a keyboard/mouse 982, audio I/O devices 988, and a storage device 990, such as a hard disk drive, solid-state drive, or another storage device for storing computer-executable instructions (code) 992 or data. The code 992 can comprise computer-executable instructions for performing methods described herein. Additional components that can be coupled to the second bus 980 include communication device(s) 984, which can provide for communication between the computing system 900 and one or more wired or wireless networks 986 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 902.11 standard and its supplements).

In embodiments where the communication devices 984 support wireless communication, the communication devices 984 can comprise wireless communication components coupled to one or more antennas to support communication between the computing system 900 and external devices. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 900 can comprise removable memory such as flash memory cards (e.g., SD (Secure Digital) cards), memory sticks, Subscriber Identity Module (SIM) cards). The memory in system 900 (including caches 912 and 914, memories 916 and 918, and storage device 990) can store data and/or computer-executable instructions for executing an operating system 994 and application programs 996. Example data includes web pages, text messages, images, sound files, video data, selected positions on an EUV mask blank for forming an absorber pattern to be sent to and/or received from one or more network servers or other devices by the system 900 via the one or more wired or wireless networks 986, or for use by the system 900. The system 900 can also have access to external memory or storage (not shown) such as external hard drives or cloud-based storage.

The operating system 994 can control the allocation and usage of the components illustrated in FIG. 9 and support the one or more application programs 996. The application programs 996 can include common computing system applications (e.g., email applications, calendars, contact managers, web browsers, messaging applications) as well as other computing applications, such as an EDA applications or applications that control an EUV mask making tool.

In some embodiments, a hypervisor (or virtual machine manager) operates on the operating system 994 and the application programs 996 operate within one or more virtual machines operating on the hypervisor. In these embodiments, the hypervisor is a type-2 or hosted hypervisor as it is running on the operating system 994. In other hypervisor-based embodiments, the hypervisor is a type-1 or “bare-metal” hypervisor that runs directly on the platform resources of the computing system 994 without an intervening operating system layer.

In some embodiments, the applications 996 can operate within one or more containers. A container is a running instance of a container image, which is a package of binary images for one or more of the applications 996 and any libraries, configuration settings, and any other information that one or more applications 996 need for execution. A container image can conform to any container image format, such as Docker®, Appc, or LXC container image formats. In container-based embodiments, a container runtime engine, such as Docker Engine, LXU, or an open container initiative (OCI)-compatible container runtime (e.g., Railcar, CRI-O) operates on the operating system (or virtual machine monitor) to provide an interface between the containers and the operating system 994. An orchestrator can be responsible for management of the computing system 900 and various container-related tasks such as deploying container images to the computing system 994, monitoring the performance of deployed containers, and monitoring the utilization of the resources of the computing system 994.

The computing system 900 can support various additional input devices, such as a touchscreen, touchpad, or trackpad, and one or more output devices, such as one or more displays. Any of the input or output devices can be internal to, external to, or removably attachable with the system 900. External input and output devices can communicate with the system 900 via wired or wireless connections.

It is to be understood that FIG. 9 illustrates only one example computing system architecture. Computing systems based on alternative architectures can be used to implement technologies described herein. For example, instead of the processors 902 and 904 and the graphics engine 952 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 9. Moreover, the illustrated components in FIG. 9 are not required or all-inclusive, as shown components can be removed and other components added in alternative embodiments.

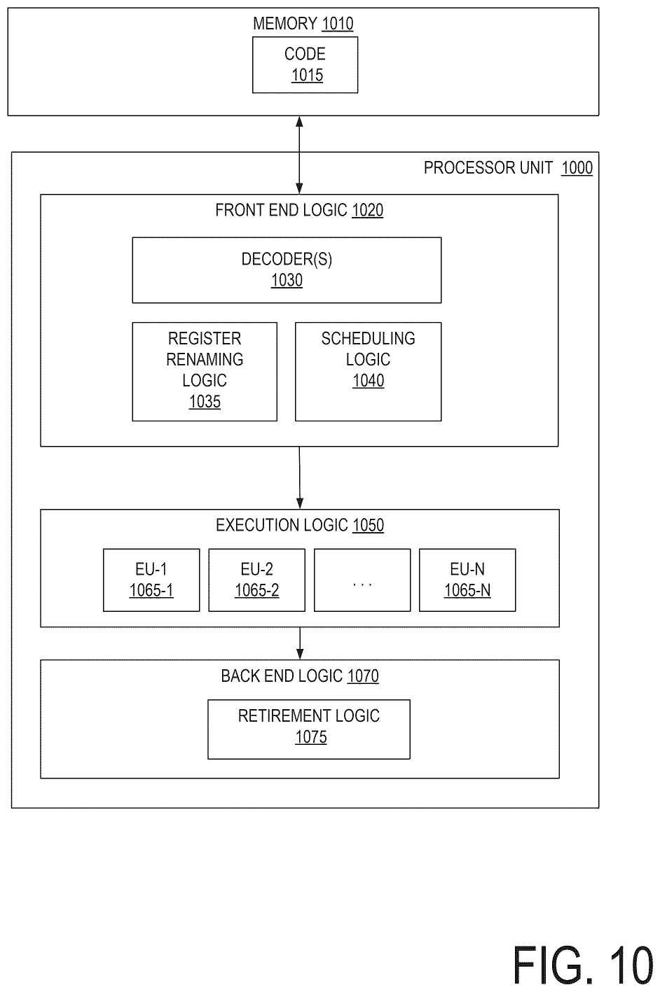

FIG. 10 is a block diagram of an example processor unit 1000 to execute computer-executable instructions as part of implementing technologies described herein. The processor unit 1000 can be a single-threaded core or a multithreaded core in that it may include more than one hardware thread context (or “logical processor”) per processor unit.

FIG. 10 also illustrates a memory 1010 coupled to the processor unit 1000. The memory 1010 can be any memory described herein or any other memory known to those of skill in the art. The memory 1010 can store computer-executable instructions 1015 (code) executable by the processor unit 1000.

The processor unit comprises front-end logic 1020 that receives instructions from the memory 1010. An instruction can be processed by one or more decoders 1030. The decoder 1030 can generate as its output a micro-operation such as a fixed width micro-operation in a predefined format, or generate other instructions, microinstructions, or control signals, which reflect the original code instruction. The front-end logic 1020 further comprises register renaming logic 1035 and scheduling logic 1040, which generally allocate resources and queues operations corresponding to converting an instruction for execution.

The processor unit 1000 further comprises execution logic 1050, which comprises one or more execution units (EUs) 1065-1 through 1065-N. Some processor unit embodiments can include a number of execution units dedicated to specific functions or sets of functions. Other embodiments can include only one execution unit or one execution unit that can perform a particular function. The execution logic 1050 performs the operations specified by code instructions. After completion of execution of the operations specified by the code instructions, back-end logic 1070 retires instructions using retirement logic 1075. In some embodiments, the processor unit 1000 allows out of order execution but requires in-order retirement of instructions. Retirement logic 1075 can take a variety of forms as known to those of skill in the art (e.g., re-order buffers or the like).

The processor unit 1000 is transformed during execution of instructions, at least in terms of the output generated by the decoder 1030, hardware registers and tables utilized by the register renaming logic 1035, and any registers (not shown) modified by the execution logic 1050.

As used herein, the term “module” refers to logic that may be implemented in a hardware component or device, software or firmware running on a processor unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processor units, state machine circuitry, and/or firmware that stores instructions executable by programmable circuitry. Modules described herein may, collectively or individually, be embodied as circuitry that forms a part of a computing system. Thus, any of the modules can be implemented as circuitry, such as possible position analysis circuitry or selected position selection circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system, device, or machine described or mentioned herein as well as any other computing system, device, or machine capable of executing instructions. Thus, the term “computer-executable instruction” refers to instructions that can be executed by any computing system, device, or machine described or mentioned herein as well as any other computing system, device, or machine capable of executing instructions.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or Fs of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is a method comprising: determining one or more candidate positions for forming an absorber pattern on an extreme ultraviolet (EUV) mask blank, the EUV mask blank comprising a plurality of buried defects, the absorber pattern comprising a plurality of absorber regions, the absorber pattern corresponding to a mask layer, the mask layer corresponding to an integrated circuit design, the mask layer comprises a plurality of polygons, wherein determining the one or more candidate positions is based at least in part on connectivity information for one or more polygons of the plurality of polygons, wherein, for individual of the one or more candidate positions, the plurality of buried defects are located within zero or more empty regions of the mask layer or coincide with zero or more dummy polygons of the mask layer; selecting one of the one or more candidate positions for forming the absorber pattern on the EUV mask blank as a selected position for forming the absorber pattern on the EUV mask blank; and storing information indicating the selected position for forming the absorber pattern on the EUV mask blank.

Example 2 comprises the method of Example 1, wherein the mask layer is a first mask layer, the connectivity information indicating one of the one or more polygons of the plurality of polygons is conductively coupled to a polygon on a second mask layer corresponding to the integrated circuit design.

Example 3 comprises the method of Example 1, the connectivity information comprising information indicating one of the one or more polygons of the plurality of polygons is conductively coupled to an active device.

Example 4 comprises the method of Example 3, wherein the active device is a transistor.

Example 5 comprises the method of Example 1, the connectivity information indicating one of the one or more polygons of the plurality of polygons is conductively coupled to a passive device.

Example 6 comprises the method of any one of Examples 1-5, wherein the connectivity information is stored in a graph data structure.

Example 7 comprises the method of Example 6, wherein determining the one or more candidate positions for forming an absorber pattern on an EUV mask blank comprises determining that a polygon of the plurality of polygons is one of the zero or more dummy polygon of the mask layer via traversal of the graph data structure.

Example 8 comprises the method of any one of Examples 1-6, wherein, for the selected position, all buried defects in the plurality of buried defects are located within one or more empty regions of the mask layer.

Example 9 comprises the method of any one of Examples 1-6, wherein, in the selected position, for individual buried defects of the plurality of buried defects located within an empty region, the individual buried defect is located at least a threshold distance away from a nearest polygon of the plurality of polygons in the mask layer.

Example 10 comprises the method of any one of Examples 1-6, wherein the selected position is a candidate position of the one or more candidate positions having a lowest number of buried defects that coincide with the zero or more dummy polygons in the mask layer.

Example 11 comprises the method of any one of Examples 1-6, wherein for individual candidate positions of the one or more candidate positions, individual of the buried defects of the plurality of buried defects located within an empty region of the zero or more empty regions of the mask layer is a minimum distance from a nearest polygon of the plurality of polygons, wherein the selected position is the candidate position having the greatest sum of the minimum distances.

Example 12 comprises the method of any one of Examples 1-6, wherein the selected position is a candidate position of the one or more candidate positions for which a minimum distance from any buried defects of the plurality of buried defects located within in an empty region of the mask layer to any polygon of the plurality polygons is the greatest among the one or more candidate positions.

Example 13 comprises the method of any one of Examples 1-12, wherein individual of the candidate positions are located at an offset from a base position on the EUV mask blank.

Example 14 comprises the method of Example 13, wherein if a candidate position of the one or more candidate positions is the base position on the EUV mask blank, the base position on the EUV mask blank is selected as the selected position.

Example 15 comprises the method of Example 13, wherein the offset comprises an x-dimension offset and a y-dimension offset.

Example 16 comprises the method of Example 15, wherein the x-dimension offset is a multiple of an x-dimension offset step size.

Example 17 comprises the method of Example 15, wherein the y-dimension offset is a multiple of an y-dimension offset step size.

Example 18 comprises the method of Example 15, wherein the x-dimension offset can vary over an x-offset range, the x-offset range based on a difference between a length of an available area on the EUV mask blank for forming the absorber pattern and a length of the mask layer.

Example 19 comprises the method of Example 15, wherein the y-dimension offset can vary over an y-offset range, the y-offset range based on a difference between a width of an available area on the EUV mask blank for forming the absorber pattern and a width of the mask layer.

Example 20 comprises the method of Example 13, wherein the offset comprises an angle offset and a radial distance offset.

Example 21 comprises the method of Example 20, wherein the angle offset is a multiple of an angle offset step size.

Example 22 comprises the method of Example 20, wherein the radial distance offset is a multiple of a radial distance offset step size.

Example 23 comprises the method of any one of Examples 1-22, further comprising sending information indicating the selected position for forming the absorber pattern on the EUV mask blank to an EUV mask-making tool.

Example 24 comprises the method of any one of Examples 1-23, further comprising, using an EUV mask-making tool, forming the absorber pattern on a surface of the EUV mask blank at the selected position for forming the absorber pattern on the EUV mask blank.

Example 25 is an apparatus, comprising: one or more processing units; and one or more computer-readable storage media storing computer-executable instructions that, when executed, cause one or more computing system to perform the method of any one of Examples 1-23.

Example 26 comprises one or more computer-readable storage media storing computer-executable instructions that, when executed, cause one or more computing systems to perform the method of any one of Examples 1-24.

Example 27 is a computing system comprising: a determining means for determining one or more candidate positions for forming an absorber pattern on an extreme ultraviolet (EUV) mask blank, the EUV mask blank comprising a plurality of buried defects, the absorber pattern comprising a plurality of absorber regions, the absorber pattern corresponding to a mask layer, the mask layer corresponding to an integrated circuit design, the mask layer comprises a plurality of polygons; a selection means for selecting one of the one or more candidate positions for forming the absorber pattern on the EUV mask blank as a selected position for forming the absorber pattern on the EUV mask blank; one or more processing units; and one or more computer-readable instructions that, when executed, cause the one or more processing units to store information indicating the selected position for forming the absorber pattern on the EUV mask blank.

Example 28 comprises the computing system of Example 27, wherein individual of the candidate positions are located at an offset from a base position on the EUV mask blank.

Example 29 comprises the computing system of Example 28, wherein the offset comprises an x-dimension offset and a y-dimension offset.

Example 30 comprises the computing system of Example 29, wherein the x-dimension offset is a multiple of an x-dimension offset step size.

Example 31 comprises the computing system of Example 29, wherein the y-dimension offset is a multiple of an y-dimension offset step size.

Example 32 comprises the computing system of Example 29, wherein the x-dimension offset can vary over an x-offset range, the x-offset range based on a difference between a length of an available area on the EUV mask blank for forming the absorber pattern and a length of the mask layer.

Example 33 comprises the computing system of Example 29, wherein the y-dimension offset can vary over an y-offset range, the y-offset range based on a difference between a width of an available area on the EUV mask blank for forming the absorber pattern and a width of the mask layer.

Example 34 comprises the computing system of Example 28, wherein the offset comprises an angle offset and a radial distance offset.

Example 35 comprises the computing system of Example 34, wherein the angle offset is a multiple of an angle offset step size.

Example 36 comprises the computing system of Example 34, wherein the radial distance offset is a multiple of a radial distance offset step size.

Example 37 comprises the computing system of any one of Examples 27-36, wherein the one or more computer-readable instructions are further to send information indicating the selected position for forming the absorber pattern on the EUV mask blank to an EUV mask-making tool.

1. A method comprising:
determining one or more candidate positions for forming an absorber pattern on an extreme ultraviolet (EUV) mask blank, the EUV mask blank comprising a plurality of buried defects, the absorber pattern comprising a plurality of absorber regions, the absorber pattern corresponding to a mask layer, the mask layer corresponding to an integrated circuit design, the mask layer comprises a plurality of polygons, wherein determining the one or more candidate positions is based at least in part on connectivity information for one or more polygons of the plurality of polygons, wherein, for individual of the one or more candidate positions, the plurality of buried defects are located within zero or more empty regions of the mask layer or coincide with zero or more dummy polygons of the mask layer;
selecting one of the one or more candidate positions for forming the absorber pattern on the EUV mask blank as a selected position for forming the absorber pattern on the EUV mask blank; and
storing information indicating the selected position for forming the absorber pattern on the EUV mask blank.

2. The method of claim 1, wherein the mask layer is a first mask layer, the connectivity information indicating one of the one or more polygons of the plurality of polygons is conductively coupled to a polygon on a second mask layer corresponding to the integrated circuit design.

3. The method of claim 1, the connectivity information comprising information indicating one of the one or more polygons of the plurality of polygons is conductively coupled to an active device.

4. The method of claim 1, wherein the connectivity information is stored in a graph data structure and determining the one or more candidate positions for forming an absorber pattern on an EUV mask blank comprises determining that a polygon of the plurality of polygons is one of the zero or more dummy polygons of the mask layer via traversal of the graph data structure.

5. The method of claim 1, wherein, for the selected position, all buried defects in the plurality of buried defects are located within one or more empty regions of the mask layer.

6. The method of claim 1, wherein, in the selected position, for individual of the plurality of buried defects located within an empty region, the individual buried defect is located at least a threshold distance away from a nearest polygon of the plurality of polygons in the mask layer.

7. The method of claim 1, wherein the selected position is a candidate position of the one or more candidate positions having a lowest number of buried defects that coincide with the zero or more dummy polygons in the mask layer.

8. The method of claim 1, wherein individual of the one or more candidate positions are located at an offset from a base position on the EUV mask blank.

9. The method of claim 8, wherein if a candidate position of the one or more candidate positions is the base position on the EUV mask blank, the base position on the EUV mask blank is selected as the selected position.

10. The method of claim 8, wherein the offset comprises an x-dimension offset and a y-dimension offset.

11. The method of claim 1, further comprising sending information indicating the selected position for forming the absorber pattern on the EUV mask blank to an EUV mask-making tool.

12. The method of claim 1, further comprising, using an EUV mask-making tool, forming the absorber pattern on a surface of the EUV mask blank at the selected position for forming the absorber pattern on the EUV mask blank.

13. A computing system comprising:
one or more processing units; and
one or more computer-readable storage media storing computer-executable instructions that, when executed, cause one or more computing system to:
determine one or more candidate positions for forming an absorber pattern on an extreme ultraviolet (EUV) mask blank, the EUV mask blank comprising a plurality of buried defects, the absorber pattern comprising a plurality of absorber regions, the absorber pattern corresponding to a mask layer, the mask layer corresponding to an integrated circuit design, the mask layer comprises a plurality of polygons, wherein determining the one or more candidate positions is based at least in part on connectivity information for one or more polygons of the plurality of polygons, wherein, for individual of the one or more candidate positions, the plurality of buried defects are located within zero or more empty regions of the mask layer or coincide with zero or more dummy polygons of the mask layer;
select one of the one or more candidate positions for forming the absorber pattern on the EUV mask blank as a selected position for forming the absorber pattern on the EUV mask blank; and
store information indicating the selected position for forming the absorber pattern on the EUV mask blank.

14. The computing system of claim 13, wherein, for the selected position, all buried defects in the plurality of buried defects are located within one or more empty regions of the mask layer.

15. The computing system of claim 13, wherein the selected position is a candidate position of the one or more candidate positions having a lowest number of buried defects that coincide with the zero or more dummy polygons in the mask layer.

16. One or more computer-readable storage media storing computer-executable instructions that, when executed, cause a computing system to:
determine one or more candidate positions for forming an absorber pattern on an extreme ultraviolet (EUV) mask blank, the EUV mask blank comprising a plurality of buried defects, the absorber pattern comprising a plurality of absorber regions, the absorber pattern corresponding to a mask layer, the mask layer corresponding to an integrated circuit design, the mask layer comprises a plurality of polygons, wherein determining the one or more candidate positions is based at least in part on connectivity information for one or more polygons of the plurality of polygons, wherein, for individual of the one or more candidate positions, the plurality of buried defects are located within zero or more empty regions of the mask layer or coincide with zero or more dummy polygons of the mask layer;
select one of the one or more candidate positions for forming the absorber pattern on the EUV mask blank as a selected position for forming the absorber pattern on the EUV mask blank; and
store information indicating the selected position for forming the absorber pattern on the EUV mask blank.

17. The one or more computer-readable storage media of claim 16, wherein the mask layer is a first mask layer, the connectivity information indicating one of the one or more polygons of the plurality of polygons is conductively coupled to a polygon on a second mask layer corresponding to the integrated circuit design.

18. The one or more computer-readable storage media of claim 16, the connectivity information comprising information indicating one of the one or more polygons of the plurality of polygons is conductively coupled to an active device.

19. The one or more computer-readable storage media of claim 16, wherein, for the selected position, all buried defects in the plurality of buried defects are located within one or more empty regions of the mask layer.

20. The one or more computer-readable storage media of claim 16, wherein the selected position is a candidate position of the one or more candidate positions having a lowest number of buried defects that coincide with the zero or more dummy polygons in the mask layer.
